(19) United States
(12) Patent Application Publication
(10) Pub. No.: US 2025/0257443 A1
(43) Pub. Date: Aug. 14, 2025

(54) SYSTEM AND METHOD FOR ATOMIC-SCALE FABRICATION

(71) Applicant: UT-Battelle, LLC, Oak Ridge, TN (US)

(72) Inventors: Ondrej E. Dyck, Powell, TN (US); Stephen Jesse, Knoxville, TN (US); Andrew R. Lupini, Knoxville, TN (US); Jacob Swett, Washington, DC (US)

(21) Appl. No.: 19/047,925

(22) Filed: Feb. 7, 2025

Related U.S. Application Data
(60) Provisional application No. 63/551,104, filed on Feb. 8, 2024.

(51) Int. Cl. C23C 14/30; C23C 14/18; C23C 14/54

(52) U.S. Cl. CPC C23C 14/30; C23C 14/18; C23C 14/541

(57) ABSTRACT

A method for atomic-scale fabrication is provided. The method includes: positioning a growth substrate in a vacuum environment to minimize contamination and to enable precise deposition; heating the growth substrate to an elevated temperature; employing a focused electron beam to induce atomic-scale modifications of the growth substrate while at the elevated temperature; and supplying a source material for deposition through an in situ delivery system, wherein the in situ delivery system includes thermal evaporation of the source material. The focused electron beam induces localized defects or nucleation sites in the growth substrate, such that incoming atoms from the source material form chemical bonds with the localized defects.

### CROSS-REFERENCE TO RELATED APPLICATIONS

This application claims the benefit of U.S. Provisional Application 63/551,104, filed Feb. 8, 2024, the disclosure of which is incorporated by reference in its entirety.

### STATEMENT REGARDING FEDERALLY SPONSORED RESEARCH AND DEVELOPMENT

This invention was made with government support under Contract No. DE-AC05-00OR22725 awarded by the U.S. Department of Energy. The government has certain rights in the invention.

### BACKGROUND OF THE INVENTION

Molecular beam epitaxy (MBE) is a popular method for supplying atomic or molecular beams of material to a substrate for the growth of thin, high-purity layers. This technique applies the same or substantially similar conditions (such as temperature and pressure) to the entire target substrate to facilitate spontaneous growth of the desired structure. This represents a so-called “global” fabrication/synthesis strategy in that global conditions (e.g., partial pressures, temperature etc.) are used to elicit spontaneous growth of the desired material. MBE can be an extremely clean growth strategy, which can allow very high-purity growth or tight composition control. Cleanliness is critical for atomic-scale fabrication. Defects can be atomic in size, such as vacancies, but are induced globally, across the material, without much positional control.

Electron beam induced deposition (EBID) uses a different approach toward material growth. Typically, an organometallic precursor gas is injected at or near to the target substrate. An electron or ion beam is then used to dissociate the precursor gas, leaving a (usually metallic) deposit on the substrate. In this manner, material can be added in a spatially defined way by positioning the beam over the desired deposition site. This strategy is akin to 3D printing. One drawback of EBID is that the precursor gas usually leaves impure material deposits. For example, a metal carbonyl, Me(CO)ₓ, precursor source gas contains significant amounts of carbon, some of which remains in the deposited material and might have to be removed by post-processing.

Both MBE and EBID use global descriptions of chemical and atomic processes. In other words, both processes are concerned with what happens on average. Because MBE places a high priority on cleanliness and perfect crystal growth, the atomic scale chemical interaction and atom dynamics are carefully considered. With EBID the exact chemistry of the deposited material is unknown and, because the substrate may vary from one location to another, an atomistic understanding of the detailed atomic dynamics and chemical interactions is often lacking.

### SUMMARY OF THE INVENTION

An improved method for atomic-scale fabrication is provided. The method includes: positioning a growth substrate in a vacuum environment to minimize contamination and to enable precise deposition; heating the growth substrate to an elevated temperature; employing a focused electron beam to induce atomic-scale modifications of the growth substrate while at the elevated temperature; and supplying a source material for deposition through an in situ delivery system, wherein the in situ delivery system includes thermal evaporation of the source material. The focused electron beam induces localized defects or nucleation sites in the growth substrate, such that incoming atoms from the source material form chemical bonds with the localized defects.

In another embodiment, a system for atomic-scale fabrication is provided. The system includes a vacuum chamber for housing a growth substrate therein. The system also includes a substrate heating platform, which regulates the temperature of the growth substrate to control atomic mobility and bonding dynamics. The system further includes an in situ delivery system to supply an atomized source material for deposition. The source material is delivered through thermal evaporation, eliminating the need for physical attachment of the source material to the growth substrate prior to deposition. Lastly, the system includes a scanning transmission electron microscope (STEM) to focus an electron beam to atomic-scale resolution. This focused electron beam interacts with the growth substrate to induce localized defects in the substrate lattice. These defects act as attachment points for the incoming atoms from the source material, enabling the formation of strong chemical bonds and facilitating precise atomic-scale deposition.

Unlike traditional EBID, where the electron beam modifies the source material directly—often leading to contamination and non-atomic precision in the deposited material—the present invention modifies the substrate itself. By altering the substrate to induce deposition and attachment, the present invention achieves cleaner, more controlled outcomes with true atomic-level precision. In some embodiments, the source material is housed in a dedicated reservoir, being physically separated from the substrate. This separation allows the source material to be delivered to the region of interest only as required. By isolating these two components, the present invention can fine-tune both the deposition environment and the material supply, ensuring high-quality, targeted deposition with minimal interference. This separation also minimizes unintended interactions between the source material and the substrate. Further embodiments of the present invention disclosed herein include additional methods to refine and expand on these core principles, providing a comprehensive technology for atomic-scale fabrication and deposition.

The embodiments described herein offer an innovative approach to deliver atomized materials for the precise insertion and bonding of atoms at specifically defined locations on a support substrate. The precise location for atom placement is determined using an atomic-resolution electron beam, which enables spatial accuracy at the atomic scale. As set forth below, the substrate temperature is carefully adjusted to influence the bonding dynamics of atoms on the substrate surface. Additionally, the surrounding atmosphere is maintained under vacuum conditions to minimize unwanted contamination and to enhance precision.

In still other embodiments, the method and the system include two or more source materials. The temperature of each source material can be independently adjusted to modulate the rate of atomized material delivery. In an optimized implementation, several heating mechanisms for different source materials can be employed to provide even greater control. This flexibility allows for the concurrent use of multiple source materials, each with distinct properties. By leveraging differences in their physical or thermal characteristics, it is possible to use a single source to deliver multiple materials, provided that their mobility can be selectively activated at distinct temperatures. Further, the user of laser ablation as an alternatively or complementary method for sourcing atomized material is also envisioned. This comprehensive set of controls—electron beam location, substrate temperature, atmosphere, and material supply—enables precise manipulation at the atomic level, paving the way for advancements in graphene-based technologies and other nanoscale innovations.

These and other features of the invention will be more fully understood and appreciated by reference to the description of the embodiments.

### BRIEF DESCRIPTION OF THE FIGURES

FIG. 1 is a flow chart illustrating a method for the precise insertion and bonding of atoms at specifically defined locations on a support substrate.

FIG. 2 is a block diagram of a system for the precise insertion and bonding of atoms at specifically defined locations on a support substrate.

FIGS. 3(a)-3(e) illustrate the atomic bonding of a source material to a modified growth substrate in accordance with one embodiment.

FIGS. 4(a)-4(e) illustrate the atomic bonding of a tin source material to a modified graphene growth substrate in accordance with a laboratory example.

### DETAILED DESCRIPTION OF THE CURRENT EMBODIMENTS

As discussed herein, the current embodiments relate to a method and a system for atomic-scale fabrication on a growth substrate. The method and the system include the accumulation of source material(s) atoms into vacancies in a growth lattice, for example a graphene growth substrate. The precise location for atom placement is determined using an atomic-resolution electron beam, which enables spatial accuracy at the atomic scale. The surrounding atmosphere is maintained under vacuum conditions to minimize unwanted contamination and to enhance precision. These and other features are discussed below.

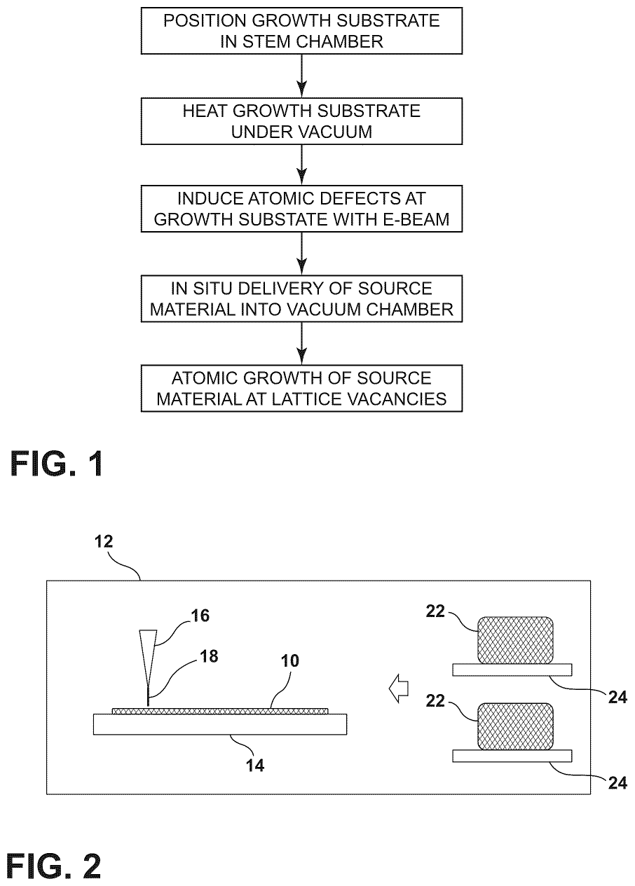

Referring first to FIGS. 1-2, the method includes positioning a growth substrate 10 within a vacuum chamber 12. The growth substrate 10 can include a crystalline substrate (e.g., having a periodic atomic arrangement) or an amorphous substrate (e.g., having a random atomic arrangement). Example crystalline substrates can include graphene and hexagonal boron nitride. Example amorphous substrates can include silicon dioxide, amorphous silicon, or glass. In the illustrated embodiment, the growth substrate 10 optionally comprises single-layer or multi-layer graphene having a pristine lattice structure. More specifically, the growth substrate 10 includes a single sheet of carbon atoms with an uninterrupted lattice structure that is substantially free from vacancies, impurities, or contamination. Multi-layer growth substrates can also be used, optionally including two or more stacking graphene layers. The present invention is not limited to graphene, however. Other growth substrates can include hexagonal boron nitride, which is atomically flat and chemically inert, similar to the single-layer or multi-layer graphene growth substrate. Still other growth substrates can be used in other embodiments as desired, including amorphous growth substrates such as silicon dioxide, amorphous silicon, or glass as mentioned above.

As indicated above, the growth substrate is positioned within a vacuum chamber, and in particular, a vacuum chamber configured for scanning transmission electron microscopy. Because electron beams are extremely sensitive to interactions with matter, including gas molecules, the chamber 12 is evacuated, optionally to pressures in the range of 10⁻⁷ Torr to 10⁻⁹ Torr. The vacuum environment ensures that the electron beam remains focused and free from interference, while also minimizing the risk of unwanted chemical reactions on the sample surface.

The method then includes heating the growth substrate 10 to a desired temperature while within the vacuum chamber 12. The growth substrate 10 is positioned atop a heating holder 14 for a scanning transmission electron microscopy system. The heating holder 14 allows for a precise and stable temperature control, ranging from room temperature to several thousand degrees Celsius, with temperature being monitored with built-in thermocouples or resistance temperature detectors. Suitable heating holders are available from Protochips (Fusion and E-Chip Series), DENSsolution (Stream Series) and Hummingbird (Thermal Holder Series). The growth substrate 10 can be heated to a first temperature, optionally 500° C., and then later heated to a second, higher temperature to promote mobilization of the source atoms, optionally 900° C.

The method then includes the formation of atomic vacancies using a scanning transmission electron microscope 16. The scanning transmission electron microscope 16 is configured to focus an electron beam 18 to atomic-scale resolution onto the growth substrate 10, wherein the focused electron beam 18 induces localized defects in the substrate lattice. This is a controlled process which relies upon the ability of the electron beam 18 to interact with and displace carbon atoms from the graphene lattice. The electron beam is focused to a sub-angstrom spot size, allowing for precision targeting of specific atoms in the graphene lattice. By scanning the beam 18 over the graphene growth substrate 10 in up to two dimensions, specific areas can be selected for vacancy creation. If the electron beam energy exceeds the displacement threshold (about 20 eV for carbon in graphene), the atom is ejected from its lattice position, creating a vacancy. The removal of one carbon atom can result in a monovacancy, while the sequential displacement of adjacent carbon atoms can for divacancies, trivacancies, or larger holes in the growth substrate, depending upon the particular application.

The method then includes the in situ delivery of an atomized source material into the vacuum chamber 12. This step generally includes the thermal evaporation of one or more source materials 20, 22 to ensure the controlled deposition of the source material(s) onto the growth substrate 10. For example, a heating element can be integrated directly into a sample holder 24, allowing for localized thermal evaporation of the source material(s). In this approach, the source material is placed on or near a heater element that is integrated into the sample holder 24. The heater element is precisely controlled to heat the source material to its evaporation point. As the source material is evaporated, individual atoms or small clusters of atoms are released and travel by diffusion to the graphene substrate 10. Also by example, the heating element can be embedded within the source material, optionally being coated with a layer of the source material. Still further by example, thermal evaporation of the source material is performed using a laser to ablate the source material from a reservoir positioned near the graphene substrate 10. In this example, a focused laser beam irradiates the source material in the reservoir, leading to evaporation or ablation of the source material into a vapor phase, which travels to the graphene substrate for deposition.

The dissociated source material 20, 22 is selected to bond with the graphene substrate 14. For example, the source material 20, 22 can be selected based on its ability to form covalent bonds with carbon at vacancy sites formed by the electron beam 18. Metals that form stable bonds with carbon can include tin (Sn), platinum (Pt), gold (Au), palladium (Pd), nickel (Ni), cobalt (Co), copper (Cu), chromium (Cr), aluminum (Al), or silver (Ag). The particular choice of source material depends on the desired bonding strength, stability, and functionality, and the vacancies in the graphene growth substrate 14 create active sites for chemical bonding.

Importantly, the supply rate of the source atoms should be sufficient to match the vacancy generation rate in the growth substrate. The supply rate of the source atoms can be increased by elevating the temperature of the source material, optionally to 1100° C. or more.

To reiterate, the technology described herein offers an innovative approach to deliver atomized materials for the precise insertion and bonding of atoms at specifically defined locations on a support substrate. As set forth above, the substrate temperature is carefully adjusted to influence the bonding dynamics of atoms on the substrate surface. Additionally, the surrounding atmosphere is maintained under vacuum conditions to minimize unwanted contamination and to enhance precision. The delivery of atomized material is controlled through the temperature regulation of one or more source materials 20, 22. Each source material's temperature can be independently adjusted to modulate the rate of atomized material delivery. In an optimized implementation, several heating mechanisms for different source materials can be employed to provide even greater control. This flexibility allows for the concurrent use of multiple source materials, each with distinct properties. By leveraging differences in their physical or thermal characteristics, it is possible to use a single source to deliver multiple materials, provided that their mobility can be selectively activated at distinct temperatures. Further, the user of laser ablation as an alternatively or complementary method for sourcing atomized material is also envisioned. This comprehensive set of controls—electron beam location definition, substrate temperature, atmosphere, and material supply—enables precise manipulation at the atomic level, paving the way for advancements in graphene-based technologies and other nanoscale innovations.

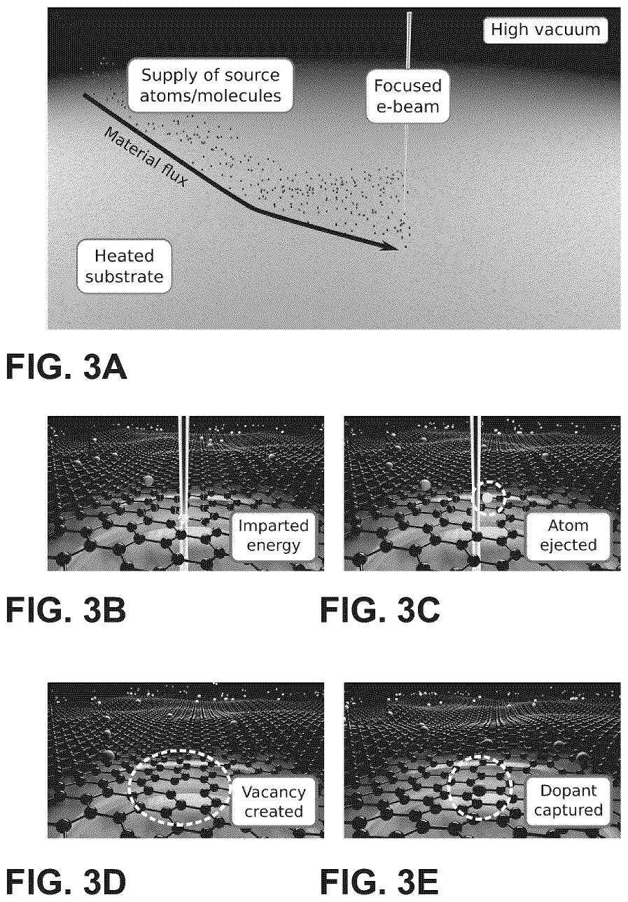

The invention is further illustrated with reference to FIGS. 3(a)-3(e). In FIG. 3(a), a focused electron beam is directed to a heated growth substrate while source atoms flow toward the heated growth substrate by diffusion. In FIG. 3(b), the imparted energy displaces a single carbon atom from the graphene lattice. The carbon atom is ejected in FIG. 3(c), creating a vacancy as shown in FIG. 3(d). A thermally diffusing atom from the source material bonds with the undercoordinated atoms around the vacancy as shown in FIG. 3(e).

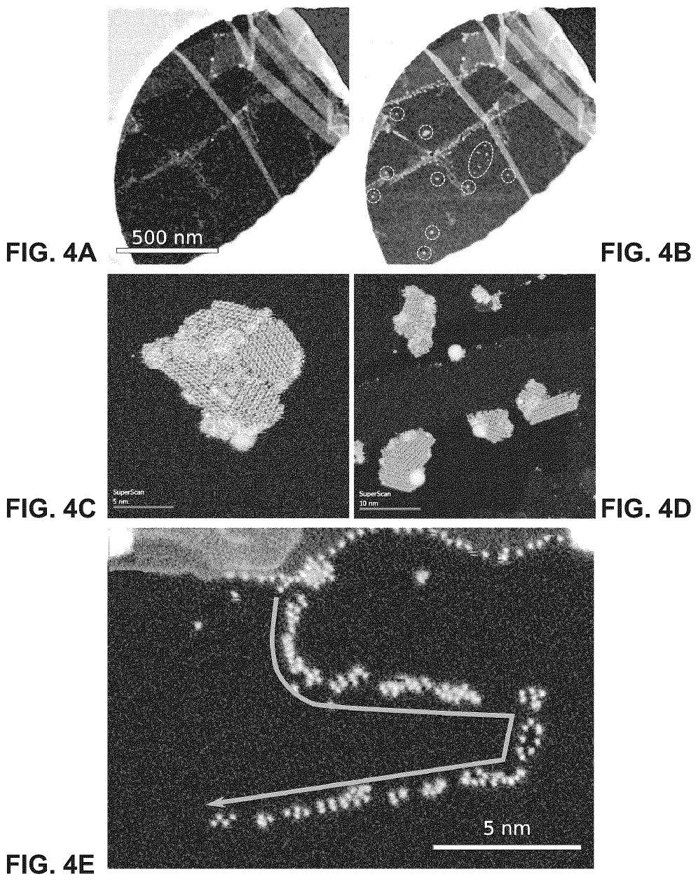

In one laboratory example, elemental tin (Sn) was coated on a tungsten (W) heat filament and then evaporated in situ onto a graphene substrate. In an initial state as shown in FIG. 4(a), the graphene substrate was held at 500° C. The W filament was then heated by applying an increased voltage bias, achieving a current of up to 100 mA. Sn nanoplatelets and nanoparticles were observed to form on the graphene substrate and along the graphene step edges, shown in FIG. 4(b). Higher magnification images of the formed nanoplatelets and nanoparticles are shown in FIGS. 4(c) and 4(d). The temperature of the growth substrate was then ramped to 900° C. to mobilize the Sn atoms. At this temperature, the Sn atoms were highly mobile at the step edges. The electron beam was then used to draw the Sn atoms from the step edge and attach them to the growth substrate. This was accomplished by continuously scanning the electron beam over a region about the size of the graphene unit cell and then manually moving the scanned region as atoms were observed to attach to the lattice, with the result being shown in FIG. 4(e).

Embodiments of the invention can enable the growth of materials under STEM observation for researchers interested in studying growth at the atomic scale. Furthermore, the attachment points can be made for the nucleation sites so that growth can be patterned, enabling predefined textures to be engineered from the top down in grown materials. Precisely positioning atoms can also have broad utility in quantum information sciences, by example.

The above description is that of current embodiments of the invention. Various alterations and changes can be made without departing from the spirit and broader aspects of the invention as defined in the appended claims, which are to be interpreted in accordance with the principles of patent law including the doctrine of equivalents. This disclosure is presented for illustrative purposes and should not be interpreted as an exhaustive description of all embodiments of the invention or to limit the scope of the claims to the specific elements illustrated or described in connection with these embodiments. For example, and without limitation, any individual element(s) of the described invention may be replaced by alternative elements that provide substantially similar functionality or otherwise provide adequate operation. This includes, for example, presently known alternative elements, such as those that might be currently known to one skilled in the art, and alternative elements that may be developed in the future, such as those that one skilled in the art might, upon development, recognize as an alternative. Further, the disclosed embodiments include a plurality of features that are described in concert and that might cooperatively provide a collection of benefits. The present invention is not limited to only those embodiments that include all of these features or that provide all of the stated benefits, except to the extent otherwise expressly set forth in the issued claims. Any reference to claim elements in the singular, for example, using the articles “a,” “an,” “the” or “said,” is not to be construed as limiting the element to the singular.

1. A method for atomic-scale fabrication, the method comprising:
positioning a growth substrate within a vacuum atmosphere and heating the growth substrate to a predetermined temperature;
employing a focused electron beam to induce atomic vacancies at the growth substrate; and
heating a source material to dissociate atoms from the source material, wherein the dissociated atoms from the source material chemically bond with growth substrate atoms that are adjacent to the atomic vacancies in the growth substrate.

2. The method of claim 1, wherein the source material comprises a metallic element or a metallic compound.

3. The method of claim 1, wherein the source material comprises an element selected from the group consisting of tin (Sn), platinum (Pt), gold (Au), palladium (Pd), nickel (Ni), cobalt (Co), copper (Cu), chromium (Cr), aluminum (Al), and silver (Ag).

4. The method of claim 1, wherein the growth substrate comprises a crystalline substrate or an amorphous substrate.

5. The method of claim 1, wherein the growth substrate comprises a graphene growth substrate or a hexagonal boron nitride growth substrate.

6. The method of claim 1, wherein heating the source material includes thermal evaporation of the source material from a heater element incorporated into a sample holder.

7. The method of claim 1, wherein heating the source material includes thermal evaporation of the source material from a heater element incorporated into the source material.

8. The method of claim 1, wherein heating the source material includes thermal evaporation of the source material from a reservoir of the source material using laser ablation.

9. The method of claim 1, further comprising moving the focused electron beam in two dimensions over the growth substrate to selectively create a plurality of attachment points and to control a spatial distribution of atomic vacancies in the growth substrate.

10. The method of claim 1, wherein the source material is a first source material, the method further comprising evaporating a second source material for supplying the second source material to the growth substrate.

11. The method of claim 1, further comprising controlling a supply rate of the dissociated atoms from the source material to be greater than or equal to a vacancy generation rate in the growth substrate.

12. A system for atomic-scale fabrication, the system comprising:
a vacuum chamber for receiving a growth substrate therein, the growth substrate including a plurality of growth substrate atoms;
a substrate heating platform for controlling a temperature of the growth substrate within the vacuum chamber;
an apparatus configured to focus an electron beam onto the growth substrate and generate atomic vacancies in the plurality of growth substrate atoms; and
an in situ delivery system for supplying an atomized source material to the growth substrate without physical attachment of the source material to the growth substrate prior to deposition, wherein dissociated atoms from the source material chemically bond with growth substrate atoms that are adjacent to the atomic vacancies in the growth substrate.

13. The system of claim 11, wherein the source material comprises a metallic element or a metallic compound.

14. The system of claim 11, wherein the source material comprise an element selected from the group consisting of tin (Sn), platinum (Pt), gold (Au), palladium (Pd), nickel (Ni), cobalt (Co), copper (Cu), chromium (Cr), aluminum (Al), and silver (Ag).

15. The system of claim 12, wherein the growth substrate comprises a crystalline substrate or an amorphous substrate.

16. The system of claim 12, wherein the growth substrate comprises a graphene growth substrate or a hexagonal boron nitride growth substrate.

17. The system of claim 12, wherein the source material is a first source material, the system further comprising a second source material for supplying a second atomized source material to the growth substrate.

18. The system of claim 12, wherein the in situ delivery system includes a sample holder heater having a heater element incorporated therein.

19. The system of claim 12, wherein the in situ delivery system includes a heater element coated with the source material.

20. The system of claim 12, wherein the in situ delivery system includes a reservoir of the source material and a laser for ablating the source material.

21. The system of claim 12, wherein the apparatus is configured to move the electron beam in two dimensions over the growth substrate.

22. The system of claim 21, wherein the apparatus is further configured to control a spatial distribution of atomic vacancies in the growth substrate.
